(19) United States
(12) Patent Application Publication
(10) Pub. No.: US 2023/0163126 A1
(43) Pub. Date: May 25, 2023

(54) PARASITIC CAPACITANCE REDUCTION FOR TALL NANOSHEET DEVICES

(71) Applicant: INTERNATIONAL BUSINESS MACHINES CORPORATION, ARMONK, NY (US)

(72) Inventors: Ruilong Xie, Niskayuna, NY (US); Heng Wu, Guilderland, NY (US); Alexander Reznicek, Troy, NY (US); Oleg Gluschenkov, Tannersville, NY (US)

(21) Appl. No.: 17/455,935

(22) Filed: Nov. 22, 2021

(51) Int. Cl. H01L 27/092; H01L 29/06; H01L 29/423; H01L 29/417; H01L 29/786; H01L 21/02; H01L 21/764; H01L 21/8238; H01L 29/66

(52) U.S. Cl. CPC H01L 27/092; H01L 29/0665; H01L 29/42392; H01L 29/41733; H01L 29/78696; H01L 21/0259; H01L 21/764; H01L 21/823807; H01L 21/823878; H01L 21/823871; H01L 29/66742

(57) ABSTRACT

A semiconductor device comprising a first channel region located on a substrate and a second channel region located on the substrate. A metal gate that extends across the first channel to the second channel and an air gap located in the metal gate, wherein the air gap is located between the first channel region and the second channel region, wherein the metal gate is located on top of the air gap.

### BACKGROUND

The present invention generally relates to the field of nano devices, and more particularly creating an air gap inside the gate to reduce the parasitic capacitance between a gate and source/drain contact.

Complementary metal-oxide-semiconductor (CMOS) cell height of nano devices are scaling smaller and smaller. The number of fins in the nano device are being reduced from multiple fins to single fins as the scaling is reduced. To achieve the enough effective gate width (Weff), the height of the fins needs to be increased and so does the gate, and this increases the parasitic capacitance between the gate and S/D contact.

### BRIEF SUMMARY

Additional aspects and/or advantages will be set forth in part in the description which follows and, in part, will be apparent from the description, or may be learned by practice of the invention.

A semiconductor device that includes a first channel region located on a substrate and a second channel region located on the substrate. A metal gate that extends across the first channel to the second channel and an air gap located in the metal gate, where the air gap is located between the first channel region and the second channel region, where the metal gate is located on top of the air gap.

A semiconductor device that includes a first channel region located on a substrate, where the first channel region includes a plurality of first nanosheet. A second channel region located on the substrate, where the second channel region includes a plurality of second nanosheets. A metal gate that extends across the first channel to the second channel, where the metal gate is locate all around the plurality of first nanosheets and the plurality of second nanosheets. An air gap located in the metal gate, where the air gap is located between the first channel region and the second channel region, wherein the metal gate is located on top of the air gap.

A method that includes forming a first channel region located on a substrate, where the first channel region includes a plurality of first nanosheets. Forming a second channel region located on the substrate, where the second channel region includes a plurality of second nanosheets. Forming a metal gate that extends across the first channel to the second channel, wherein the metal gate is locate all around the plurality of first nanosheets and the plurality of second nanosheets. Forming an air gap located in the metal gate, wherein the air gap is located between the first channel region and the second channel region, wherein the metal gate is located on top of the air gap.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a nano device, in accordance with an embodiment of the present invention.

FIG. 2 illustrates cross section A of the nano device after nanosheet stack has been patterned and shallow trench isolation has been formed, in accordance with the embodiment of the present invention.

FIG. 3 illustrates cross section B of the nano device after nanosheet stack has been patterned and shallow trench isolation has been formed, in accordance with the embodiment of the present invention.

FIG. 4 illustrates cross section A of the nano device after forming a conformal dielectric liner and a dummy gate spacer, in accordance with the embodiment of the present invention.

FIG. 5 illustrates cross section B of the nano device after forming a conformal dielectric liner and a dummy gate spacer, in accordance with the embodiment of the present invention.

FIG. 6 illustrates cross section A of the nano device after formation of the filler layer, in accordance with the embodiment of the present invention.

FIG. 7 illustrates cross section B of the nano device after formation of the filler layer, in accordance with the embodiment of the present invention.

FIG. 8 illustrates cross section A of the nano device after deposition of additional dummy gate and gate hardmask, in accordance with the embodiment of the present invention.

FIG. 9 illustrates cross section B of the nano device after deposition of additional dummy gate and gate hardmask, in accordance with the embodiment of the present invention.

FIG. 10 illustrates cross section A of the nano device after gate patterning, removal of first layer, and formation of the gate spacer and bottom dielectric isolation, in accordance with the embodiment of the present invention.

FIG. 11 illustrates cross section B of the nano device after gate patterning, removal of first layer, and formation of the gate spacer and bottom dielectric isolation, in accordance with the embodiment of the present invention.

FIG. 12 illustrates cross section C of the nano device after gate patterning, removal of first layer, and formation of the gate spacer and bottom dielectric isolation, in accordance with the embodiment of the present invention.

FIG. 13 illustrates cross section A of the nano device after formation of the inner spacer and the source/drain epi, in accordance with the embodiment of the present invention.

FIG. 14 illustrates cross section B of the nano device after formation of the inner spacer and the source/drain epi, in accordance with the embodiment of the present invention.

FIG. 15 illustrates cross section C of the nano device after formation of the inner spacer and the source/drain epi, in accordance with the embodiment of the present invention.

FIG. 16 illustrates cross section A of the nano device after gate spacer pull down at sidewall of S/D epi, followed by formation of a sacrificial epi over the S/D epi, in accordance with the embodiment of the present invention.

FIG. 17 illustrates cross section B of the nano device after gate spacer pull down at sidewall of S/D epi, followed by formation of a sacrificial epi over the S/D epi, in accordance with the embodiment of the present invention.

FIG. 18 illustrates cross section C of the nano device after gate spacer pull down at sidewall of S/D epi, followed by formation of a sacrificial epi over the S/D epi, in accordance with the embodiment of the present invention.

FIG. 19 illustrates cross section A of the nano device after formation of an interlayered dielectric (ILD) layer and a CMP process, in accordance with the embodiment of the present invention.

FIG. 20 illustrates cross section B of the nano device after formation of an interlayered dielectric (ILD) layer and a CMP process, in accordance with the embodiment of the present invention.

FIG. 21 illustrates cross section C of the nano device after formation of an interlayered dielectric (ILD) layer and a CMP process, in accordance with the embodiment of the present invention.

FIG. 22 illustrates cross section A of the nano device after removing the dummy gate and sacrificial layers selective to surrounding materials, including the filler layer, in accordance with the embodiment of the present invention.

FIG. 23 illustrates cross section B of the nano device after removing the dummy gate and sacrificial layers selective to surrounding materials, including the filler layer 195, in accordance with the embodiment of the present invention.

FIG. 24 illustrates cross section C of the nano device after removing the dummy gate and sacrificial layers selective to surrounding materials, including the filler layer, in accordance with the embodiment of the present invention.

FIG. 25 illustrates cross section A of the nano device after formation of the replacement gate, in accordance with the embodiment of the present invention.

FIG. 26 illustrates cross section B of the nano device after formation of the replacement gate, in accordance with the embodiment of the present invention.

FIG. 27 illustrates cross section C of the nano device after formation of the replacement gate, in accordance with the embodiment of the present invention.

FIG. 28 illustrates cross section A of the nano device after formation of a patterning mask layer, in accordance with the embodiment of the present invention.

FIG. 29 illustrates cross section B of the nano device after formation of a patterning mask layer and the formation of a channel to the filler layer, in accordance with the embodiment of the present invention.

FIG. 30 illustrates cross section C of the nano device after formation of a patterning mask layer, in accordance with the embodiment of the present invention.

FIG. 31 illustrates cross section A of the nano device after removal of the filler layer, in accordance with the embodiment of the present invention.

FIG. 32 illustrates cross section B of the nano device after removal of the filler layer, in accordance with the embodiment of the present invention.

FIG. 33 illustrates cross section C of the nano device after removal of the filler layer, in accordance with the embodiment of the present invention.

FIG. 34 illustrates cross section A of the nano device after formation of the cavity liner, in accordance with the embodiment of the present invention.

FIG. 35 illustrates cross section B of the nano device after formation of the cavity liner, in accordance with the embodiment of the present invention.

FIG. 36 illustrates cross section C of the nano device after formation of the cavity liner, in accordance with the embodiment of the present invention.

FIG. 37 illustrates cross section A of the nano device after filling in the channel, in accordance with the embodiment of the present invention.

FIG. 38 illustrates cross section B of the nano device after filling in the channel, in accordance with the embodiment of the present invention.

FIG. 39 illustrates cross section C of the nano device after filling in the channel, in accordance with the embodiment of the present invention.

FIG. 40 illustrates cross section A of the nano device after formation of the gate cap, in accordance with the embodiment of the present invention.

FIG. 41 illustrates cross section B of the nano device after formation of the gate cap, in accordance with the embodiment of the present invention.

FIG. 42 illustrates cross section C of the nano device after formation of the gate cap and exposing the source/drain epi to form plate P₂, in accordance with the embodiment of the present invention.

FIG. 43 illustrates cross section A of the nano device after formation of the contact plate, in accordance with the embodiment of the present invention.

FIG. 44 illustrates cross section B of the nano device after formation of the contact plate, in accordance with the embodiment of the present invention.

FIG. 45 illustrates cross section C of the nano device after formation of the contact plate, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. Nano devices having a tall nanosheet stack is desirable because it reduces the footprint size of the devices. When the height of the FINFET or nanosheet stack is tall (e.g., greater than or equal 100 nm), it allows for achieving an effective gate width (W_{eff}) with a reduction in footprint size. However, increasing the height of the nano sheet stack causes an increase in the height of the gate. The overlap between the nanosheet stack/gate and the S/D contact creates the natural parasitic capacitor, where increasing the height of the gate causes the capacitance of the natural capacitor to increase. The resulting capacitance of the capacitor is considered a parasitic capacitance since it adversely affects the performance of the device. Capacitance of the natural parasitic capacitor can be reduced by limiting or reducing the overlap between the nanosheet stack/gate and the S/D contact. One way to reduce the overlap between the nanosheet stack/gate and the S/D contact is achieved by creating an air gap between adjacent tall nanosheet stacks that share a gate. The gate spans across the first tall nanosheet stack (a first channel region) and a second tall nanosheet stack (a second channel region).

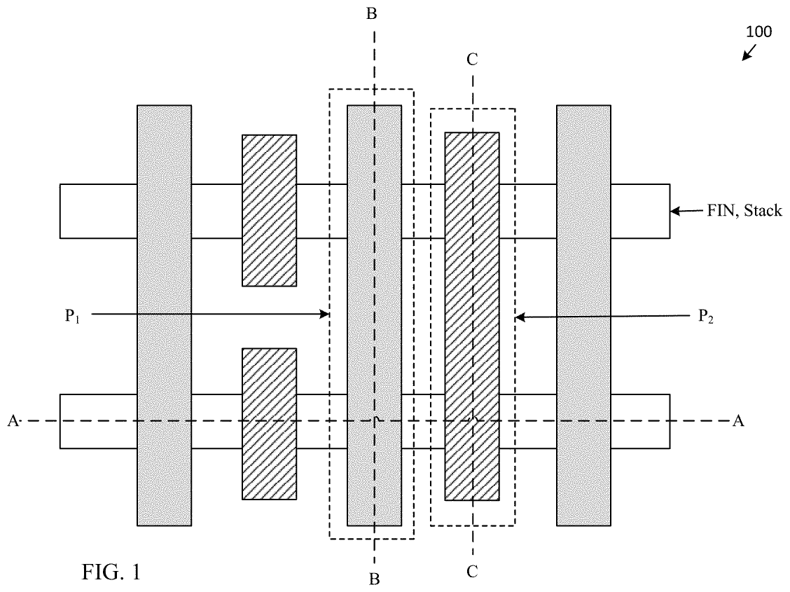

FIG. 1 illustrates a top-down view of a nano device 100, in accordance with an embodiment of the present invention. The nano device 100 includes a plurality of gates which wraps around Fins, or nanosheets, (e.g., a first plate P₁, which is a shared gate that spans across a first channel regions to a second channel region) and S/D contact (e.g., a second plate P₂), where the first plate P₁ and the second plate P₂ are parallel to each other. A natural parasitic capacitor is formed between first plate P₁ and the second plate P₂ having a capacitance. This parasitic capacitance is reduced by creating an air gap in first plate P₁ between the Fins. The formation of the air gap will be described in further detail below.

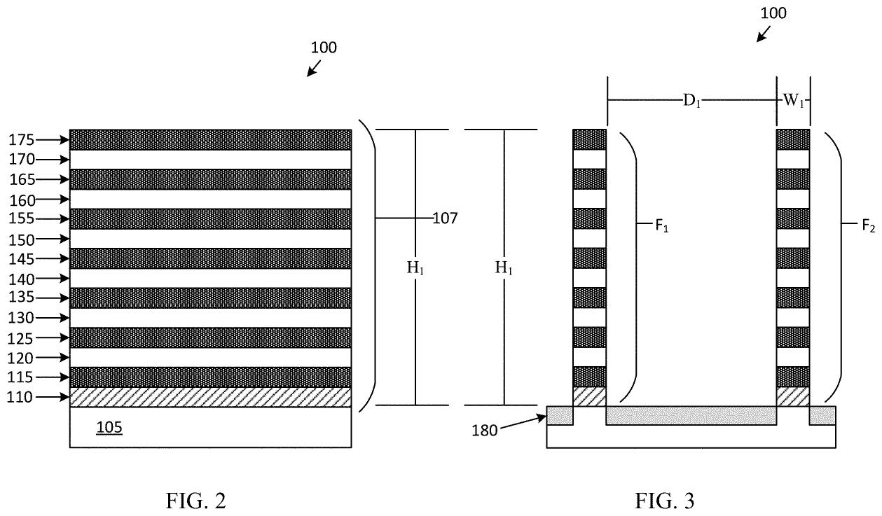

FIG. 2 illustrates cross section A of the nanosheet device 100 in accordance with the embodiment of the present invention. The nanosheet device 100 includes a substrate 105 and a nanosheet stack 107. The substrate 105 can be, for example, a material including, but not necessarily limited to, silicon (Si), silicon germanium (SiGe), silicon carbide (SiC), Si:C (carbon doped silicon), silicon germanium carbide (SiGeC), carbon doped silicon germanium (SiGe:C), III-V, II-V compound semiconductor or another like semiconductor. In addition, multiple layers of the semiconductor materials can be used as the semiconductor material of the substrate 105. In some embodiments, the substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or entire semiconductor substrate 105 may also be comprised of an amorphous, polycrystalline, or monocrystalline. The semiconductor substrate 105 may be doped, undoped or contain doped regions and undoped regions therein.

The nanosheet stack 107 includes a first layer 110, a second layer 115, a third layer 120, a fourth layer 125, a fifth layer 130, a sixth layer 135, a seventh layer 140, an eighth layer 145, a ninth layer 150, a tenth layer 155, an eleventh layer 160, a twelfth layer 165, a thirteenth layer 170, and a fourteenth layer 175. The nanosheet stack 107 is comprised of alternating layers where the combined height of all the layers gives the nanosheet stack 107 a height H1 that is greater than or equal to 100 nm. The high number of layers in the nano sheet stack 107 allows for the enough Weff for the nanosheet device to be achieved. The figures illustrate a nanosheet stack with 14 layers and more than 100 nm tall. This is meant for illustrative purposes only and it is not meant to be seen as limiting. The present invention can be applied to nanosheet stack with any number of layers and height. The first layer 110 can be comprised of, for example, SiGe, where Ge is in the range of about 45% to 70%. The nanosheet stack 107 includes a group of sacrificial layers comprised of the second layer 115, the fourth layer 125, the sixth layer 135, the eighth layer 145, the tenth layer 155, the twelfth layer 165, and the fourteenth layer 175. Each of the sacrificial layers can be comprised of, for example, SiGe, where Ge is in the range of about 15% to 35%. The nanosheet stack 107 includes a group of nano sheets comprised of the third layer 120, the fifth layer 130, the seventh layer 140, the ninth layer 150, the eleventh layer 160, and the thirteenth layer 170. Each layer of the group of nano sheets can be comprised of, for example, Si.

FIG. 3 illustrates cross section B of the nanosheet device 100 in accordance with the embodiment of the present invention. When the nanosheet stack 107 was patterned to form the first fin F₁ and the second fin F₂ a trench is formed in the substrate 105. A shallow trench isolation (STI) layer 180 is formed in the trench of the substrate 105. Each fin includes the layers the comprise the nanosheet stack 107 and each fin has a height H₁. The width W₁ of each of the fins can be smaller than conventional nanosheet device because of the increased height of the stack. For example, the width W₁ of the fins can be about 20 nm. The distance D₁ is the distance between the fins (F₁ and F₂) and the distance D₁ is greater than conventional spacing between fins. The taller and narrower fins can achieve enough W_{eff} since they include a higher number of layers. The wider distance D₁ allows wider separation between the different active regions, so S/D epi patterning or work function metal patterning in subsequent process flows can be easier. Fin F₁ is also referred to as the first channel region and fin F₂ is also referred to as the second channel region.

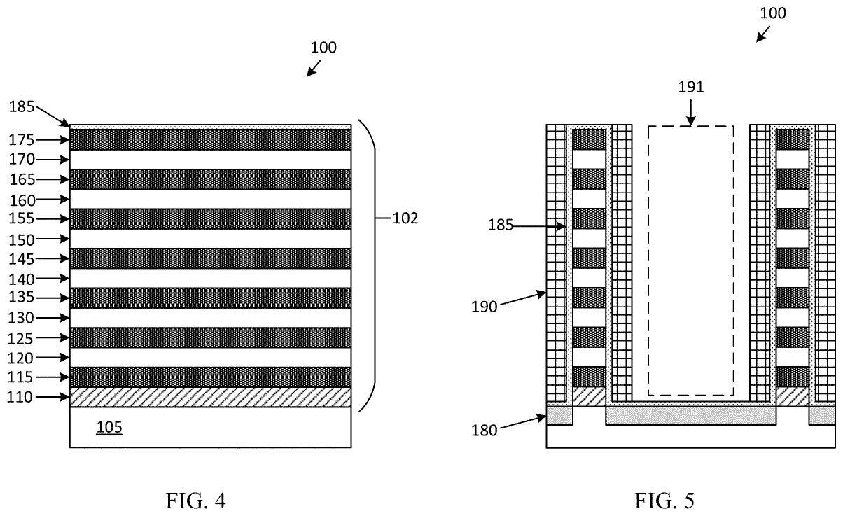

FIG. 4 illustrates cross section A of the nanosheet device 100 after forming a conformal dielectric liner 185 and a dummy gate spacer 190, in accordance with the embodiment of the present invention. A conformal dielectric liner 185 is formed on top of the fourteenth layer 175. The dielectric liner 185 can be comprised of, for example, SiO₂. FIG. 5 illustrates cross section B of the nanosheet device 100 after forming a conformal dielectric liner 185 and a dummy gate spacer 190, in accordance with the embodiment of the present invention. The dielectric liner 185 is formed on the exposed surfaces, thus forming a liner on top of the STI layer 180 and around each of the fins F₁ and F₂. A dummy gate spacer 190 is formed on top of the dielectric liner 185. The dummy gate spacer 190 can be comprised of, for example, amorphous SiGe. The dummy gate spacer 190 is formed by conformal deposition followed by anisotropic etch back by, for example, reactive ion etching (RIE), so that the dummy gate spacer 190 remains surround the sides of each of the fins F₁ and F₂. An empty space (as illustrated by dashed box 191) is formed between the dummy gate spacer 190 that is adjacent to each fin F₁ and F₂, respectively.

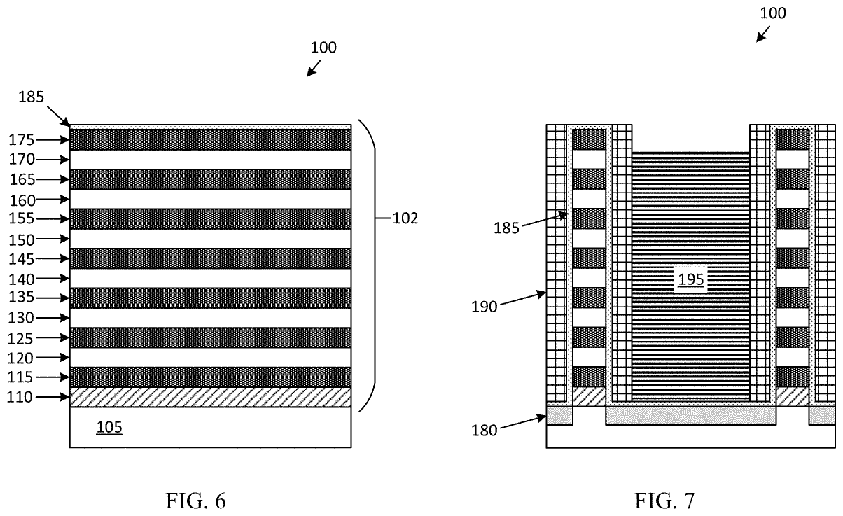

FIG. 6 illustrates cross section A of the nanosheet device 100 after formation of the filler layer 195, in accordance with the embodiment of the present invention. FIG. 7 illustrates cross section B of the nanosheet device 100 after formation of the filler layer 195, in accordance with the embodiment of the present invention. A filler layer 195 is formed in the empty space between the dummy gate spacer 190 that are adjacent to each fin F₁ and F₂, respectively. The filler layer 195 can be comprised of, for example, amorphous-Si. The filler layer 195 dictates the location where the air gap will be formed, which will be described in further detail below. The dummy gate spacer 190 acts as a spacing element so that the air gap will be spaced apart from the fins F₁ and F₂. The fill layer 195 can be formed by CVD deposition followed by a recess process so the top surface of the dielectric liner 185 is exposed.

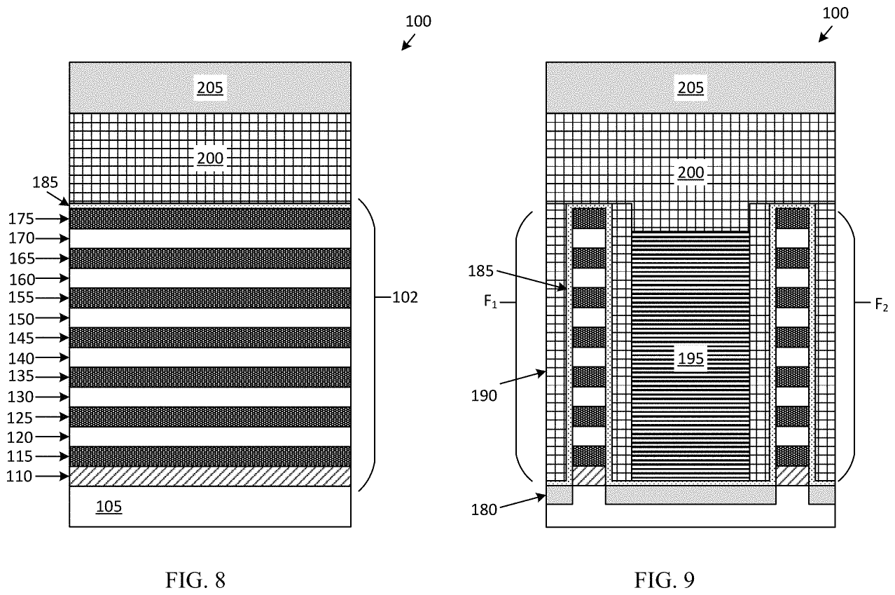

FIG. 8 illustrates cross section A of the nanosheet device 100 deposition of additional dummy gate 200 and gate hardmask 205, in accordance with the embodiment of the present invention. Additional dummy gate 200 is formed on top of the dielectric liner 185. FIG. 9 illustrates cross section B of the nanosheet device 100 after deposition of additional dummy gate 200 and gate hardmask 205, in accordance with the embodiment of the present invention. The additional dummy gate 200 is formed on top of the filler layer 195, and on top of the fins F₁ and F₂. The additional dummy gate 200 can be comprised of, for example, the same material as dummy gate spacer 190, such as SiGe. The gate hardmask 205 is formed on top of the additional dummy gate 200.

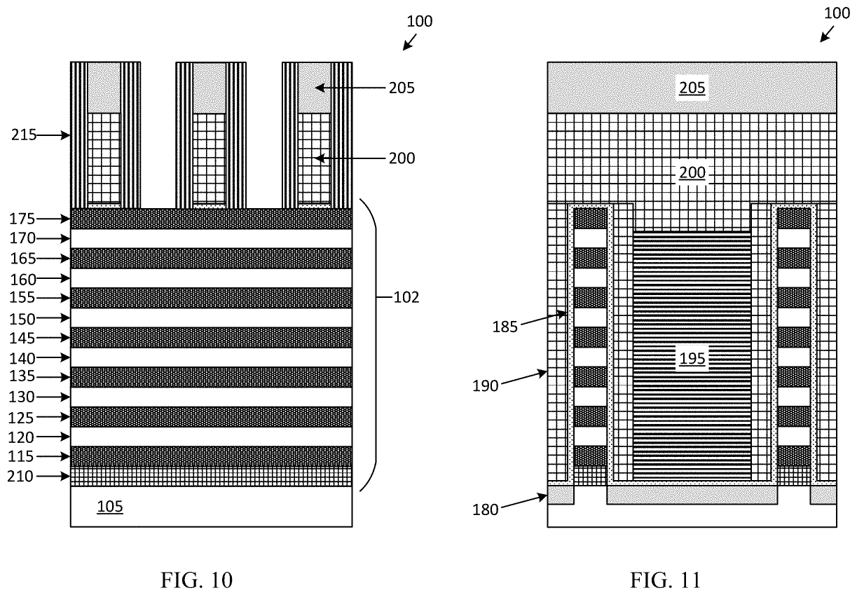

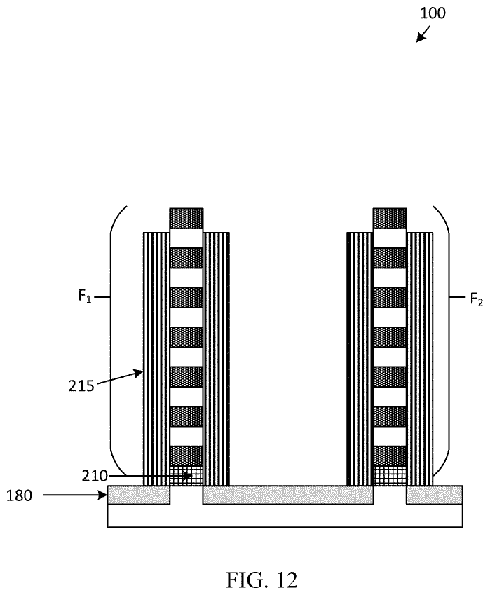

FIG. 10 illustrates cross section A of the nanosheet device 100 after gate patterning, removal of first layer 110, and formation of the gate spacer 215 and bottom dielectric isolation 210, in accordance with the embodiment of the present invention. FIG. 11 illustrates cross section B of the nano sheet device after gate patterning, removal of first layer 110, and formation of the gate spacer 215 and bottom dielectric isolation 210, in accordance with the embodiment of the present invention. FIG. 12 illustrates cross section C of the nanosheet device after gate patterning, removal of first layer 110, and formation of the gate spacer 215 and bottom dielectric isolation 210, in accordance with the embodiment of the present invention. After gate patterning, the first layer 110 is selectively removed. The first layer 110 can be selectively removed because of the higher concentration of Ge when compared to the other sacrificial layers containing Ge. The gate hardmask 205, the dummy gate spacer 190, and the additional dummy gate 200 and filler layer 195 are patterned to form multiple columns/pillars over the nanosheet fins. A gate spacer 215 is formed on the exposed surfaces of the columns/pillars (for both gates as shown in FIG. 10 and Fins as shown in FIG. 12), and it can also fill in the empty regions due to removal of first layer 110 and becomes bottom dielectric isolation 210. The gate spacer 215 is etched back by, for example, RIE, so that the second spacer 215 only remains adjacent to the columns/pillars.

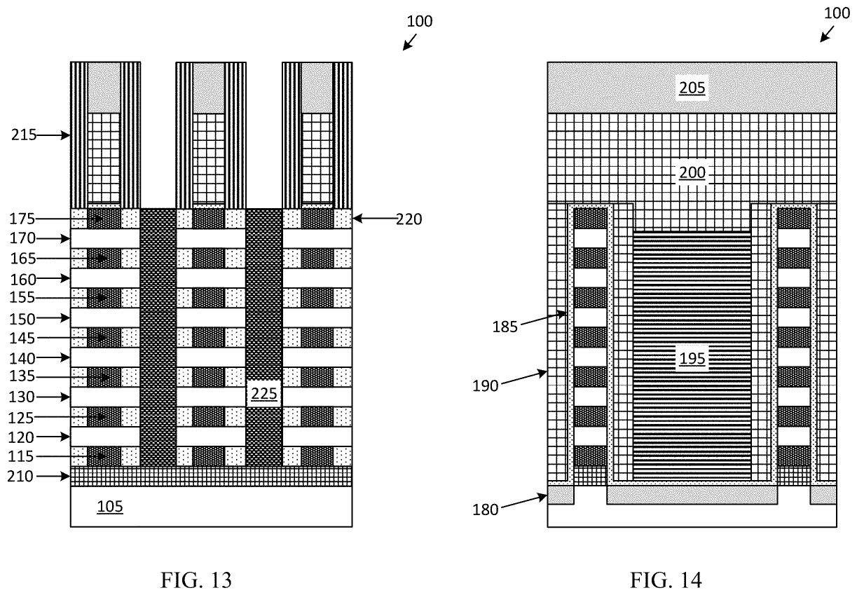

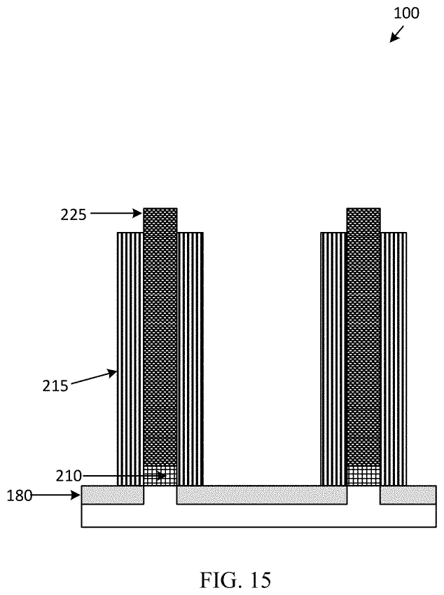

FIG. 13 illustrates cross section A of the nano sheet device 100 after formation of the inner spacer 220 and the source/drain (S/D) epi 225, in accordance with the embodiment of the present invention. FIG. 14 illustrates cross section B of the nanosheet device 100 100 after formation of the inner spacer 220 and the source/drain (S/D) epi 225, in accordance with the embodiment of the present invention. FIG. 15 illustrates cross section C of the nanosheet device 100 after formation of the inner spacer 220 and the source/drain (S/D) epi 225, in accordance with the embodiment of the present invention. The nanosheet stack 107 that is not covered by gate or spacer 215 is etched. The group of sacrificial layers (e.g., the second layer 115, the fourth layer 125, the sixth layer 135, the eighth layer 145, the tenth layer 155, the twelfth layer 165, and the fourteenth layer 175) are recessed. An inner spacer 220 is formed in the locations where the sacrificial layers were recessed. A source/drain epi 225 is formed in the space between the columns/pillars. The source/drain epi 225 can be for example, a n-type epi, or a p-type epi. For n-type epi, an n-type dopant selected from a group of phosphorus (P), arsenic (As) and/or antimony (Sb) can be used. For p-type epi, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

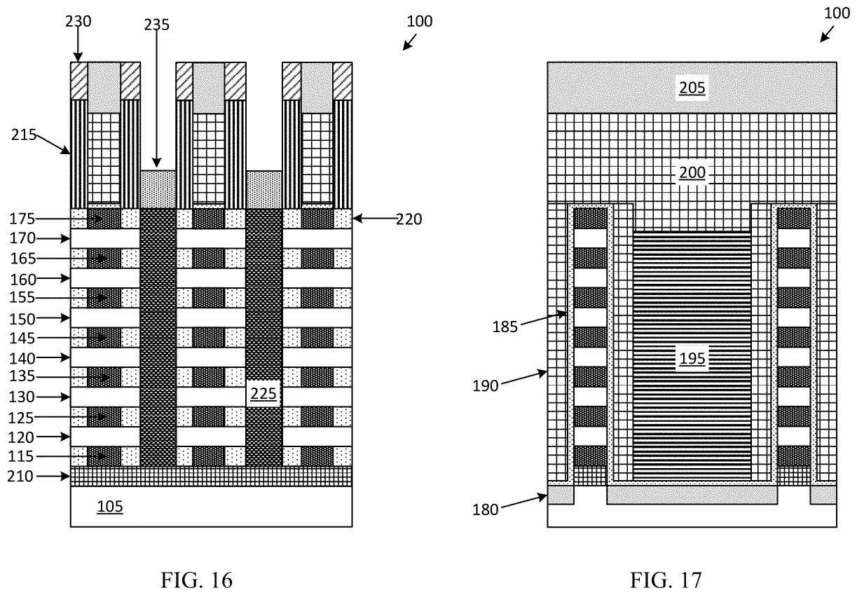

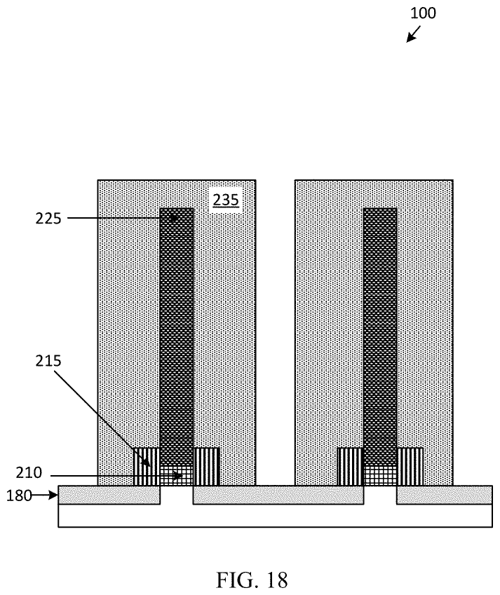

FIG. 16 illustrates cross section A of the nano sheet device 100 after gate spacer 215 pull down at sidewall of S/D epi 225, followed by formation of a sacrificial epi 235 over the S/D epi 225, in accordance with the embodiment of the present invention. FIG. 17 illustrates cross section B of the nanosheet device 100 after gate spacer pull down at sidewall of S/D epi 225, followed by formation of a sacrificial epi 235 over the S/D epi 225, in accordance with the embodiment of the present invention. FIG. 18 illustrates cross section C of the nanosheet device 100 after gate spacer pull down at sidewall of S/D epi 225, followed by formation of a sacrificial epi 235 over the S/D epi 225, in accordance with the embodiment of the present invention. The spacer 215 at S/D epi sidewall is etched down. To avoid excessive spacer 215 pull down at gate sidewall, a spacer cap 230 can be formed before the recess of spacer 215 at epi sidewall. After that, a sacrificial epi 235 is formed over the source/drain epi 225. The sacrificial epi 235 encapsulates the source/drain epi 225.

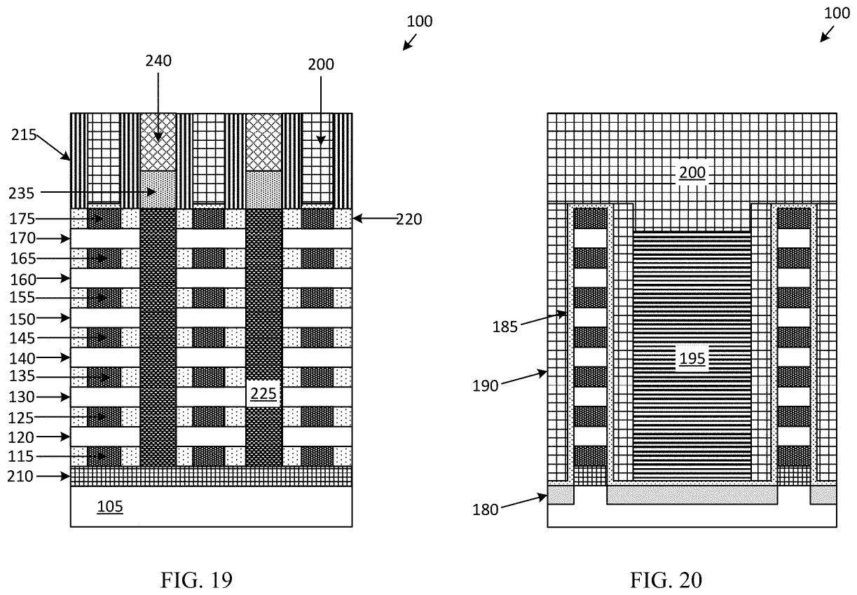

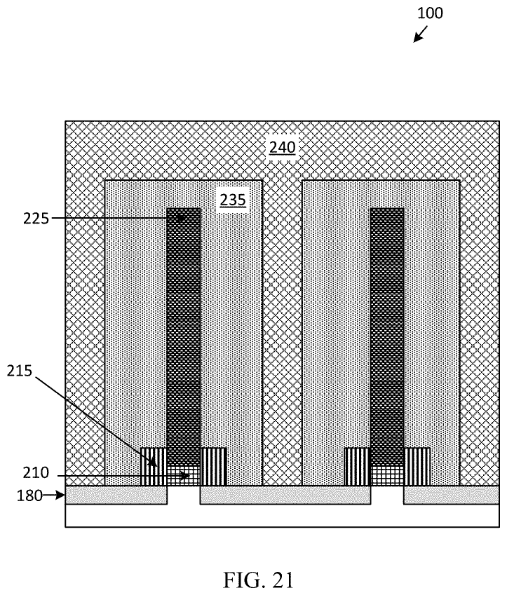

FIG. 19 illustrates cross section A of the nano sheet device 100 after formation of an interlayered dielectric (ILD) layer 240 and a CMP process, in accordance with the embodiment of the present invention. FIG. 20 illustrates cross section B of the nanosheet device after formation of an interlayered dielectric (ILD) layer 240 and a CMP process, in accordance with the embodiment of the present invention. FIG. 21 illustrates cross section C of the nanosheet device 100 after formation of an interlayered dielectric (ILD) layer 240 and a CMP process, in accordance with the embodiment of the present invention. An interlayered dielectric (ILD) layer 240 is formed on top of the sacrificial epi 235. The top of the nanosheet device 100 is planarized by, for example, chemical mechanical planarization (CMP) to remove the spacer cap 230 and the gate hardmask 205. The CMP process exposes the top surface of the dummy gate 200 and creates a uniform surface across the top of the nano sheet device 100. The ILD layer 240 is formed between sections of the sacrificial epi 235 and on top of the sacrificial epi 235.

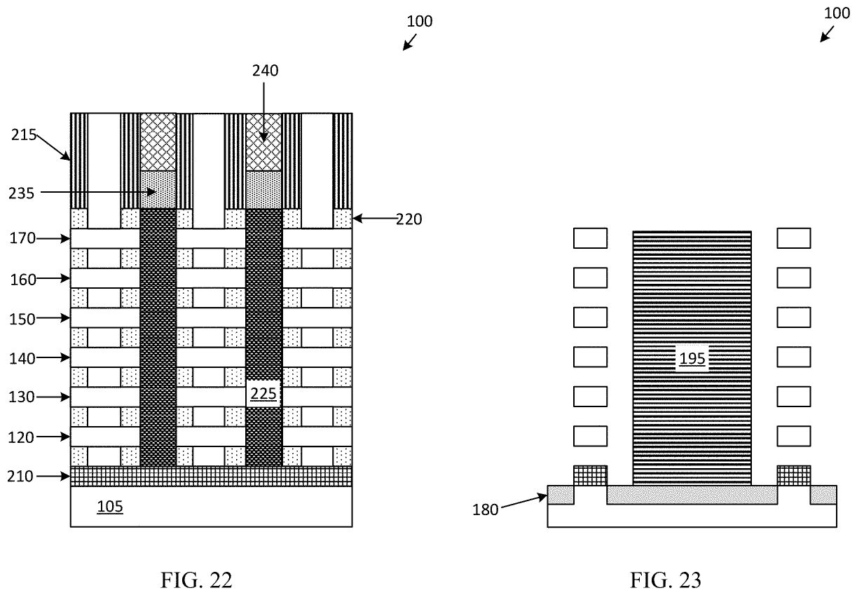

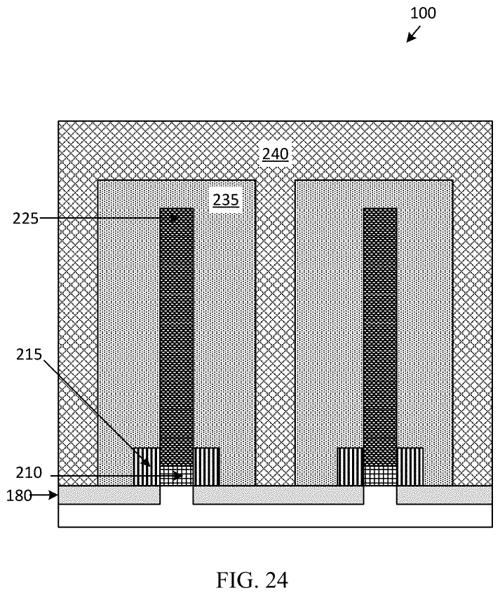

FIG. 22 illustrates cross section A of the nanosheet device 100 after removing the dummy gate spacer 190 and sacrificial layers selective to surrounding materials, including the filler layer 195, in accordance with the embodiment of the present invention. FIG. 23 illustrates cross section B of the nanosheet device 100 after removing the dummy gate spacer 190 and sacrificial layers selective to surrounding materials, including the filler layer 195, in accordance with the embodiment of the present invention. FIG. 24 illustrates cross section C of the nanosheet device 100 after removing the dummy gate spacer 190 and sacrificial layers selective to surrounding materials, including the filler layer 195, in accordance with the embodiment of the present invention. The dummy gate 200, the dummy gate spacer 190, dielectric liner 185, and the group of sacrificial layers (e.g., the second layer 115, the fourth layer 125, the sixth layer 135, the eighth layer 145, the tenth layer 155, the twelfth layer 165, and the fourteenth layer 175) are selectively removed.

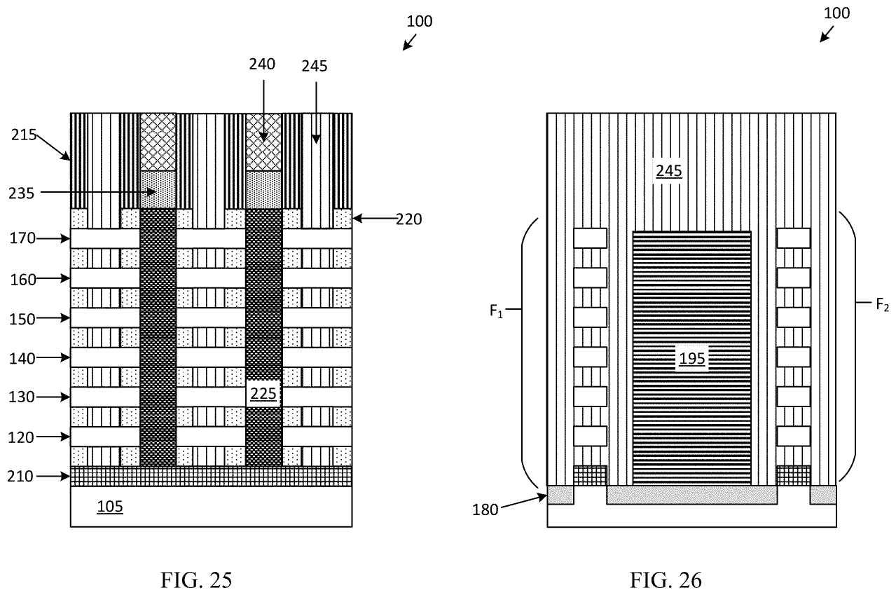

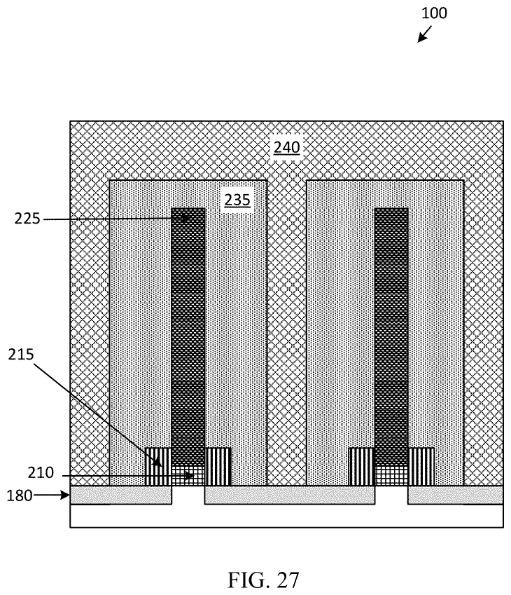

FIG. 25 illustrates cross section A of the nanosheet device 100 after formation of the replacement gate 245, in accordance with the embodiment of the present invention. FIG. 26 illustrates cross section B of the nanosheet device 100 after formation of the replacement gate 245, in accordance with the embodiment of the present invention. FIG. 27 illustrates cross section C of the nano sheet device 100 after formation of the replacement gate 245, in accordance with the embodiment of the present invention. A replacement gate 245 is formed in the space created by the removal of the layers. The replacement gate is formed all around the group of nano sheets (e.g., the third layer 120, the fifth layer 130, the seventh layer 140, the ninth layer 150, the eleventh layer 160, and the thirteenth layer 170) as illustrated by FIGS. 25 and 26. The replacement gate 245 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W. The replacement gate 245 is a shared gate that spans across fin F₁ (e.g., the first channel region) and fin F₂ (e.g., the second channel region).

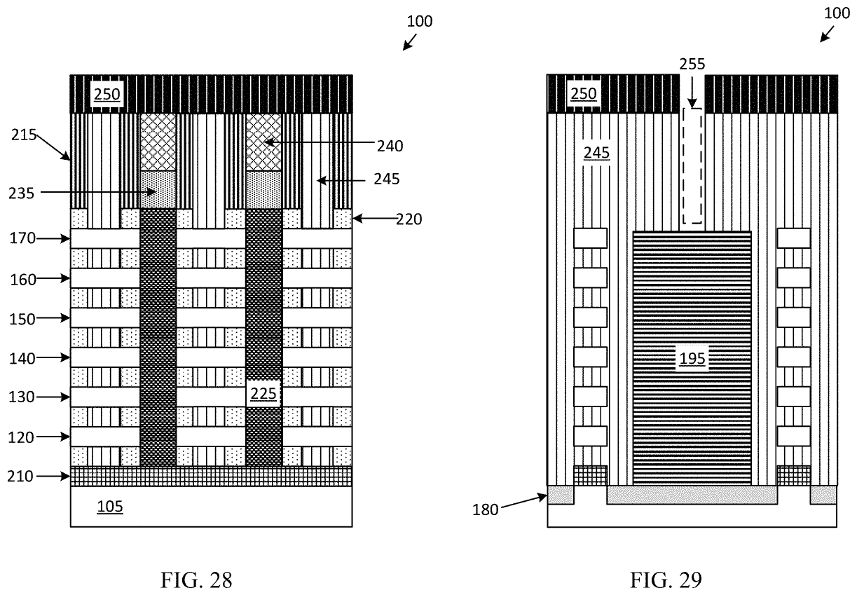

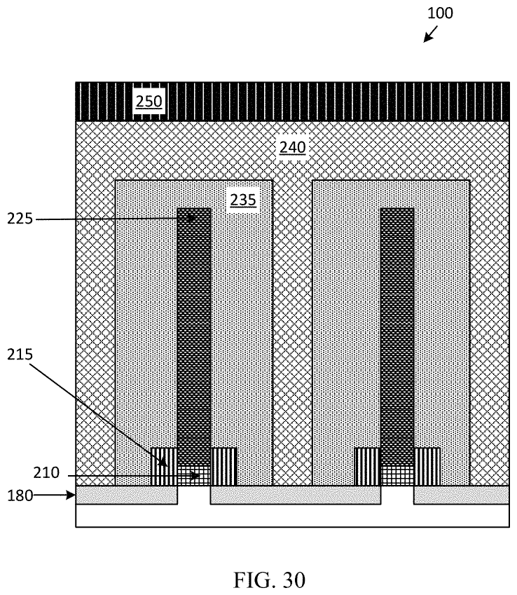

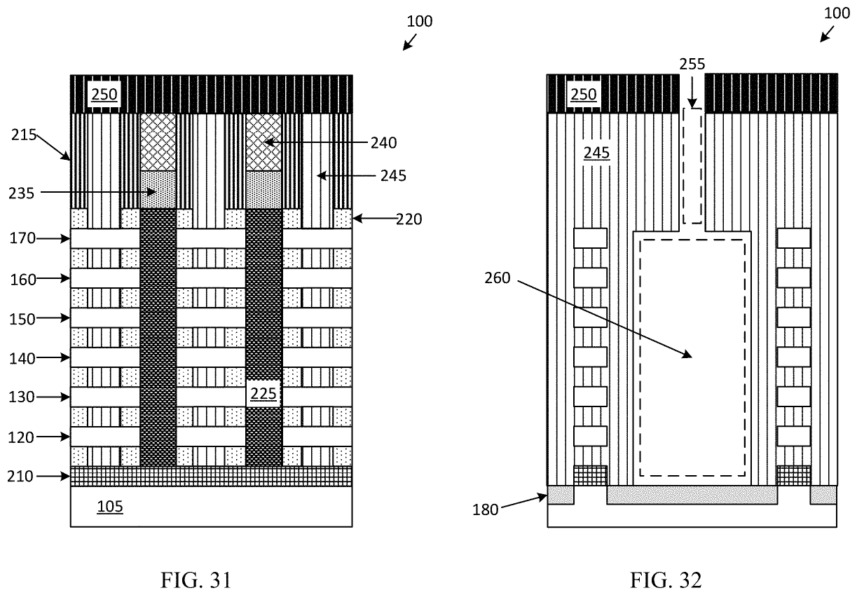

FIG. 28 illustrates cross section A of the nanosheet device 100 after formation of a patterning mask layer 250, in accordance with the embodiment of the present invention. FIG. 29 illustrates cross section B of the nanosheet device 100 after formation of a patterning mask layer 250 and the formation of a trench 255 extending to the filler layer 195, in accordance with the embodiment of the present invention. FIG. 30 illustrates cross section C of the nanosheet device 100 after formation of a patterning mask layer 250, in accordance with the embodiment of the present invention. A patterning mask layer 250 (such as hardmask material, like SiN, or soft mask material like OPL) is formed on top of the replacement gate 245 and on top of the ILD layer 240. After that, a trench 255 is patterned, such that, the trench 255 extends downwards to reach the filler layer 195.

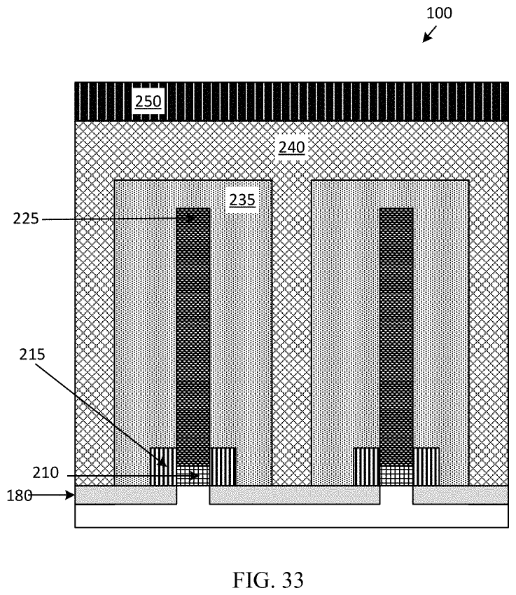

FIG. 31 illustrates cross section A of the nanosheet device 100 after removal of the filler layer 195, in accordance with the embodiment of the present invention. FIG. 32 illustrates cross section B of the nanosheet device 100 after removal of the filler layer 195, in accordance with the embodiment of the present invention. FIG. 33 illustrates cross section C of the nanosheet device 100 after removal of the filler layer 195, in accordance with the embodiment of the present invention. The trench 255 exposed the filler layer 195, thus provided access to remove the filler layer 195. The filler layer 195 is removed to form cavity 260. The cavity 260 is in the same shape and size as the filler layer 195. The cavity 260 forms the base for the formation of the air gap.

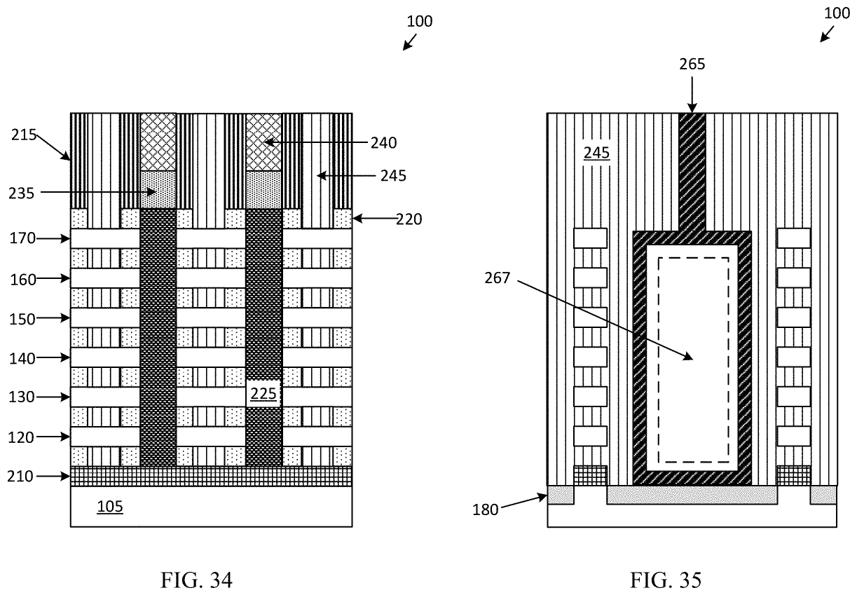

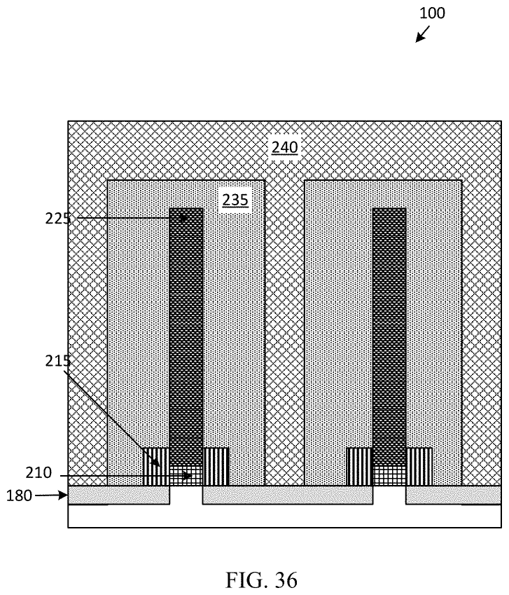

FIG. 34 illustrates cross section A of the nanosheet device 100 after formation of the cavity liner 265, in accordance with the embodiment of the present invention. FIG. 35 illustrates cross section B of the nanosheet device 100 after formation of the cavity liner 265, in accordance with the embodiment of the present invention. FIG. 36 illustrates cross section C of the nanosheet device 100 after formation of the cavity liner 265, in accordance with the embodiment of the present invention. A cavity liner 265 is deposited by, for example, atomic layered deposition (ALD), around the surfaces of the cavity 260. The trench 255 is pinched off prior to the cavity 260 from being filled with the cavity liner 265. Therefore, the air gap 267 is formed from the remaining space of the cavity 260 that was not filled with the cavity liner 265. The final size of the air gap 267 is based on the initial size of the cavity 260 and the width of the trench 255 (since the width of the trench 255 determines how long it will take to be pinched off). The thickness of the cavity liner 265 is determined based on how long it takes to pinch off the trench 255. The top of the nano device 100 is planarized by, for example, CMP, to remove the patterning mask layer 250 and to remove any excess cavity liner 265. The cavity liner 265 can be comprised of a dielectric material.

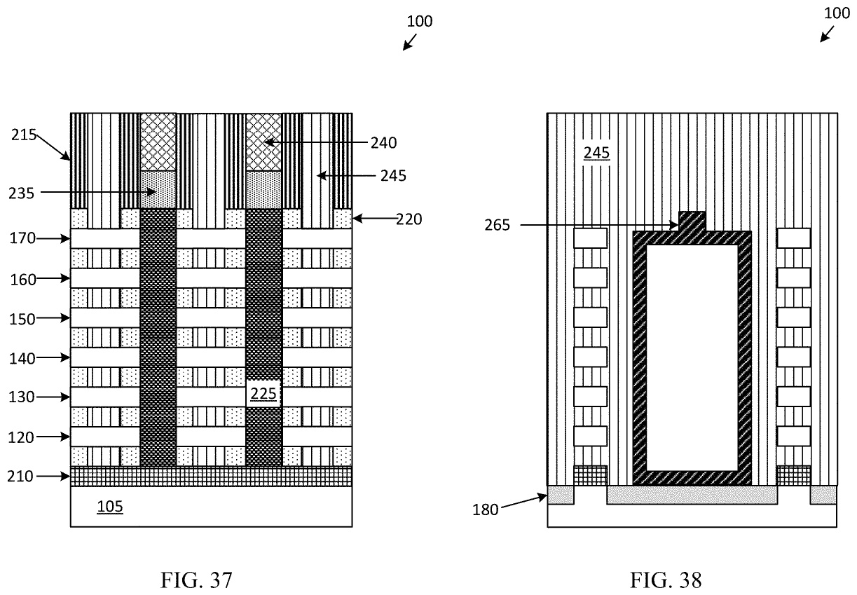

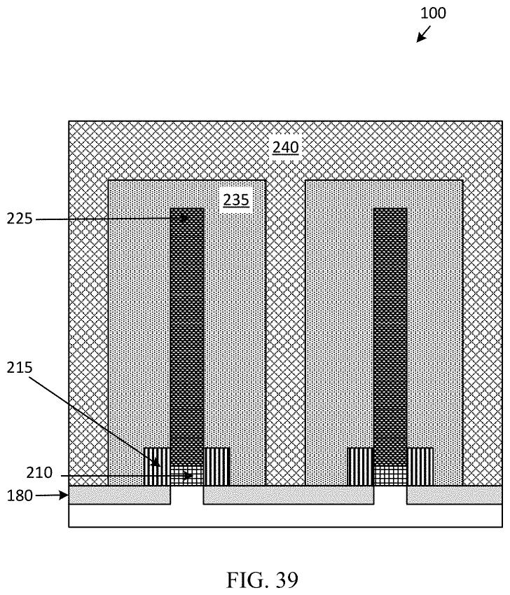

FIG. 37 illustrates cross section A of the nanosheet device 100 after filling in the trench 255, in accordance with the embodiment of the present invention. FIG. 38 illustrates cross section B of the nanosheet device 100 after filling in the trench 255, in accordance with the embodiment of the present invention. FIG. 39 illustrates cross section C of the nanosheet device 100 after filling in the trench 255, in accordance with the embodiment of the present invention. The cavity liner 265 is optionally pulled down within the trench 255 and the trench 255 is filled in with material that forms the metal gate portion of the replacement gate 245 (such as TiN, TiAlC, TiC, W, etc). Therefore, the replacement gate 245 is located on three sides of the air gap 267.

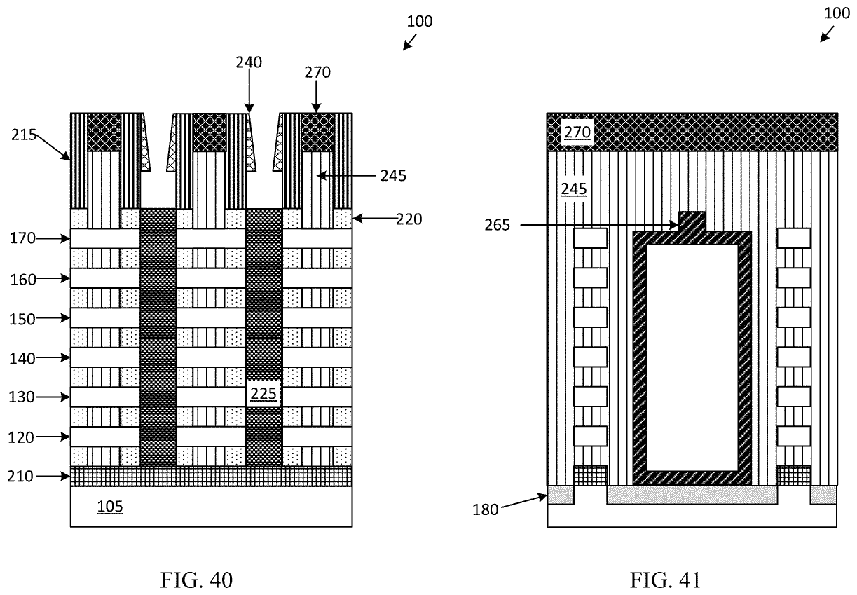

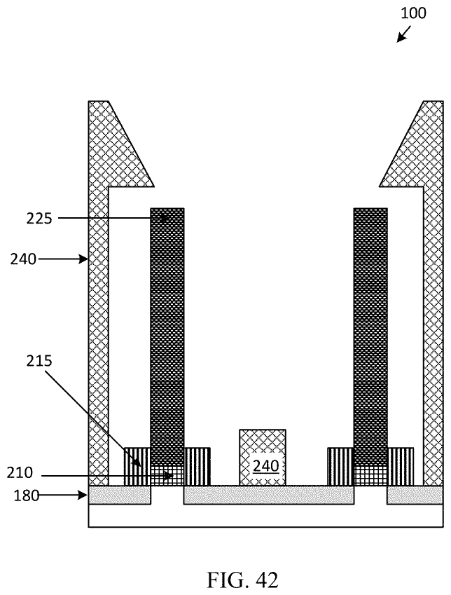

FIG. 40 illustrates cross section A of the nanosheet device 100 after formation of the gate cap 270, in accordance with the embodiment of the present invention. FIG. 41 illustrates cross section B of the nanosheet device 100 after formation of the gate cap 270, in accordance with the embodiment of the present invention. FIG. 42 illustrates cross section C of the nano sheet device 100 after formation of the gate cap 270 and exposing the source/drain epi 225 to form the second plate P₂, in accordance with the embodiment of the present invention. The replacement gate 245 is recessed back and a gate cap 270 is formed on top of the replacement gate 245. S/D contact opening is patterned using conventional lithography and etch process to form a contact opening through the ILD layer 240 to expose the sacrificial epi 235 and the sacrificial epi 235 is removed by, for example, a selective dry or wet etch process.

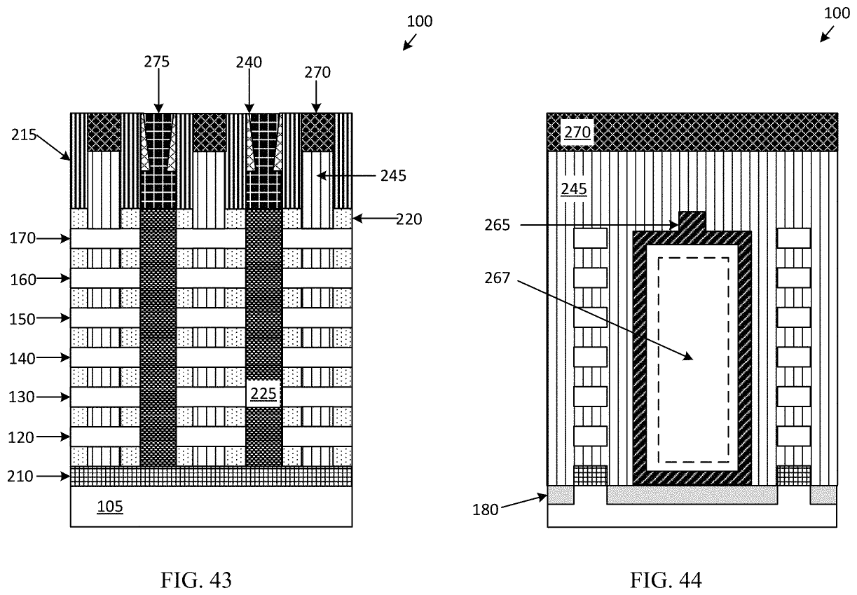

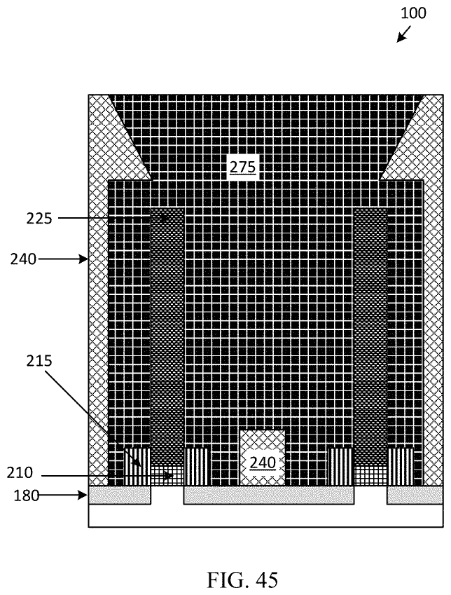

FIG. 43 illustrates cross section A of the nanosheet device 100 after formation of the contact plate 275, in accordance with the embodiment of the present invention. FIG. 44 illustrates cross section B of the nanosheet device 100 after formation of the contact plate 275, in accordance with the embodiment of the present invention. FIG. 45 illustrates cross section C of the nanosheet device 100 after formation of the contact plate 275, in accordance with the embodiment of the present invention. The contact plate 275 is formed in the empty spaced created by the removal of the ILD layer 240 and the sacrificial epi 235. The contact plate 275 is comprised of conductive metals, including silicide liner, such as Ti, Ni, NiPt, etc., metal adhesion layer, such as TiN, and conductive metal fills, such as W, Co, Ru, etc. The contact plate 275 forms the second plate P₂ of the natural parasitic capacitor as illustrated by FIG. 45.

FIG. 44 illustrates the first plate P₁ of the natural parasitic capacitor with an air gap 267. The parasitic natural capacitor is formed because of the metal in the first plate P₁ (e.g., the replacement gate 245) and the metal of the second plate P₂ (e.g., the contact plate 275). The air gap 267 located in the first plate P₁ (as illustrated by FIG. 44) reduces the overlap between the metal layers of the plates P₁ and P₂, thus the capacitance of the natural parasitic capacitor is reduced. The amount the capacitance is reduced is dependent on the size of the air gap 267 that is in the first plate P₁.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A semiconductor device comprising:
a first channel region located on a substrate;
a second channel region located on the substrate;
a metal gate that extends across the first channel to the second channel; and
an air gap located in the metal gate, wherein the air gap is located between the first channel region and the second channel region, wherein the metal gate is located on top of the air gap.

2. The semiconductor device of claim 1, further comprising:
a source/drain contact region located on the substrate that includes a metal plate, wherein the source/drain region is parallel to the metal gate.

3. The semiconductor device of claim 2, wherein a natural parasitic capacitor forms between the metal plate and the metal gate, wherein the air gap reduces a capacitance of the natural parasitic capacitor.

4. The semiconductor device of claim 1, further comprising:
a liner located within the air gap, wherein the liner extends around the air gap.

5. The semiconductor device of claim 4, wherein the liner is comprised of a dielectric material.

6. The semiconductor device of claim 5, wherein the liner is in direct contact with the metal gate.

7. The semiconductor device of claim 1, wherein the first channel region has a height greater than or equal to 100 nm.

8. The semiconductor device of claim 7, wherein the second channel region has a height greater than or equal to 100 nm.

9. The semiconductor device of claim 1, wherein the first channel region has a width of about 20 nm.

10. The semiconductor device of claim 9, wherein the second channel region has a width of about 20 nm.

11. A semiconductor device comprising:
a first channel region located on a substrate, wherein the first channel region includes a plurality of first nanosheets;
a second channel region located on the substrate, wherein the second channel region includes a plurality of second nanosheets;
a metal gate that extends across the first channel to the second channel, wherein the metal gate is locate all around the plurality of first nanosheets and the plurality of second nanosheets; and
an air gap located in the metal gate, wherein the air gap is located between the first channel region and the second channel region, wherein the metal gate is located on top of the air gap.

12. The semiconductor device of claim 11, further comprising:
a source/drain contact region located on the substrate that includes a metal plate, wherein the source/drain region is parallel to the metal gate.

13. The semiconductor device of claim 12, wherein a natural parasitic capacitor forms between the metal plate and the metal gate, wherein the air gap reduces a capacitance of the natural parasitic capacitor.

14. The semiconductor device of claim 11, further comprising:
a liner located within the air gap, wherein the liner extends around the air gap.

15. The semiconductor device of claim 14, wherein the liner is comprised of a dielectric material.

16. The semiconductor device of claim 15, wherein the liner is in direct contact with the metal gate.

17. A method comprising:
forming a first channel region located on a substrate, wherein the first channel region includes a plurality of first nanosheets;
forming a second channel region located on the substrate, wherein the second channel region includes a plurality of second nanosheets;
forming a metal gate that extends across the first channel to the second channel, wherein the metal gate is locate all around the plurality of first nanosheets and the plurality of second nanosheets; and
forming an air gap located in the metal gate, wherein the air gap is located between the first channel region and the second channel region, wherein the metal gate is located on top of the air gap.

18. The method of claim 17, further comprising:
forming a source/drain contact region located on the substrate that includes a metal plate, wherein the source/drain region is parallel to the metal gate.

19. The method of claim 18, wherein a natural parasitic capacitor forms between the metal plate and the metal gate, wherein the air gap reduces a capacitance of the natural parasitic capacitor.

20. The method of claim 17, further comprising:
forming a liner located within the air gap, wherein the liner extends around the air gap.
